(19) United States
(12) Patent Application Publication
(10) Pub. No.: US 2007/0285901 A1
(43) Pub. Date: Dec. 13, 2007

(54) CARD STRUCTURE AND METHOD OF ASSEMBLY THEREOF

(75) Inventors: Boaz Siman-Tov, Holon (IL); Micha Manassen, Pewtah Takva (IL); Eli Margalit, Ra'anana (IL)

Correspondence Address: MOTOROLA, INC;INTELLECTUAL PROPERTY SECTION, LAW DEPT, 8000 WEST SUNRISE BLVD, FT LAUDERDAL, FL, 33322, US

(73) Assignee: MOTOROLA, INC., Plantation, FL (US)

(21) Appl. No.: 11/422,983

(22) Filed: Jun. 8, 2006

(51) Int. Cl. H05K 1/14

(52) U.S. Cl. 361/737

(57) ABSTRACT

A card structure comprises a casing arranged to fit around an electrical connector. At least one foldable side tab is located on the casing such that when the at least one foldable side tab is folded it mechanically attaches the casing to the electrical connector. A method of assembling a card structure is also described comprising folding at least one foldable side tab located on a casing of the card structure around an electrical connector, such that the at least one foldable side tab mechanically attaches the casing to the electrical connector.

### FIELD OF THE INVENTION

The present invention relates generally to cards for insertion into slots, such as Personal Computer Memory Card International Association (PCMCIA) cards for insertion in a compatible computing device. The invention is applicable to, but not limited to, the assembly and secure casing of such cards.

### BACKGROUND OF THE INVENTION

In the early 1990's, the rapid growth of mobile computing drove the development of smaller, lighter, and more portable tools for information processing. One of the most exciting of these innovations was personal computer (PC) card technology. The power and versatility of PC cards quickly made them standard equipment in mobile computers. The rapid development and worldwide adoption of PC card technology has been due in large part to the standards efforts of the Personal Computer Memory Card International Association (PCMCIA).

The PCMCIA also promotes the interoperability of cards, herein called ‘PC cards’, for use not only in mobile computers, but in such diverse host products as digital cameras, cable television (TV), set-top boxes, and automobiles. Such products all contain devices which

have computing capability which are collectively referred to herein as ‘computing devices’. As the variety of such products including computing devices that need modular peripheral expansion has grown, so has the need for improved capabilities of the peripheral devices employed with the computing devices of such products. This has led to a rapid expansion of the capabilities of PC Cards.

The PC Card Standard provides physical specifications for three types of PC Cards, with additional provisions for extended cards. All three card types measure the same length and width and use the same 68-pin connector, with the only difference between the card types being thickness. The thicknesses are 3.3, 5.0, and 10.5 millimetres (0.12992, 0.19685, and 0.41339 inches respectively) for Type I, Type II, and Type III cards respectively. As they differ only in thickness, a thinner card can be used in a thicker slot; however, a thicker card can not be used in a thinner slot.

The card types each have features that fit the needs of different applications. Type I PC Cards are typically used for memory devices such as random access memory (RAM), Flash, one time programmable (OTP), and static random access memory (SRAM) cards. Type II PC Cards are typically used for I/O devices such as data/fax modems, local area networks (LANs), and mass storage devices. Type III PC Cards are used for devices whose components are thicker, such as rotating mass storage devices. Extended cards allow the addition of components that must remain outside the system for proper operation, such as antennas for wireless applications.

The rapid rate of adoption of PC Card slots has driven a steady stream of card and host implementations. During that time, PC Cards containing new technologies were introduced and significant new capabilities were added to the Standard. At the same time considerable experience was gained by card, host, and software vendors, and opportunities to improve compatibility were recognized.

With standard PCMCIA cards of the Cardbus type, only the bottom cover supports the 68-pin connector. The top cover remains open in order to leave the grounding plate dimples that contact with the mating connector. Hence, the 68-pin connector has limited mechanical support.

It will be appreciated by those of ordinary skill in the art that, by pressing the 68-pin connector down when inserting the card into the slot, the bottom cover may be pushed out. As a consequence, the slot may deform the bottom cover and prevent to plug it into the slot or subsequent slots. It has also been observed, through rigorous testing of the mechanical aspects of the card, that the bottom sheet metal cover may deform due to dropping the card or following excessive and frequent vibrations in use.

In order to address this problem, it is desirable to attach the bottom cover to the casing as securely as possible. Once the bottom cover is secure, it limits the 68-pin connector movements and prevents the bottom cover deforming due to dropping or excessive vibrations.

A known solution is to use a ‘snap-fit’ arrangement, where, for example, the casing of the bottom cover may be snapped into a plastic frame. FIG. 1 illustrates a plan view of a known casing arrangement 100 for a PCMCIA card. Notably, the casing arrangement 100 uses a front snap-fit fixing arrangement 105. With a front snap-fit fixing arrangement 105, it will be appreciated by those of ordinary skill in the art that the fixing may lack rigidity and strength and as it needs a reduced frame area (being located by the 68-pin connector), it may weaken the connector surface.

Referring now to FIG. 2, a top view of a known PC card structure 200 is illustrated, highlighting the location of the two front snap-fit fixing arrangements 105. A sectional (side) view 300 along a longitudinal edge of the PC card structure 200 is illustrated in FIG. 3 (along lines B-B), again highlighting the location of the two front snap-fit fixing arrangements 105.

Thus, the two front snap-fit fixing arrangements are manufactured as resilient metal fixing arrangements that, when assembled, are able to mechanically attach the frame onto the PC card. After the top and bottom covers have been assembled to enclose the 68-pin PC card structure, the two front snap-fit fixing arrangements 105 protrude, as illustrated in the side view 400 of the fixing arrangement in FIG. 4. For completeness, FIG. 5 illustrates a detailed view 500 of the front snap-fit arrangement 105.

One problem associated with the snap-fit approach is the lack of robustness in ensuring that a gap exists between the metal cover and the frame. Furthermore, a snap solution is known to cause conductive burrs (i.e. through metal-on-metal movement). Furthermore, a snap-fit arrangement requires a more complicated clasping feature in the frame. In addition, the retaining force of a snap-fit arrangement is limited.

Insert molding technology is used to manufacture such injection plastic frames, which requires more expensive tooling than die (metal) casting frames (that use a stainless sheet 0.2 millimetre (mm) (0.00787 inch) thickness). Both metal frames and plastic frames are known to use a separate sheet metal cover.

Thus, a need exists for an improved PC card structure and method of assembly thereof.

### BRIEF DESCRIPTION OF THE DRAWINGS

The accompanying FIGs., where like reference numerals refer to identical or functionally similar elements throughout the separate views and which together with the detailed description below are incorporated in and form part of the specification, serve to further illustrate various embodiments and to explain various principles and advantages all in accordance with the present invention

FIG. 1 illustrates a plan view of a known cover arrangement for a PCMCIA card;

FIG. 2 illustrates a top view of the PCMCIA card cover with a front snap-fit arrangement;

FIG. 3 illustrates a side view of the PCMCIA card cover with a front snap-fit arrangement;

FIG. 4 illustrates a detail view of a front snap-fit arrangement; and

FIG. 5 illustrates a detailed view of a snap-fit arrangement.

FIG. 6 illustrates a plan view of a cover for a PCMCIA card with a side bend fixing arrangement according to one embodiment of the present invention;

FIG. 7 illustrates a side view of the PCMCIA card cover with a side bend fixing arrangement according to one embodiment of the present invention;

FIG. 8 illustrates a detailed side view of the PCMCIA card cover with a side bend fixing arrangement according to one embodiment of the present invention; and

FIG. 9 illustrates a detailed view of a side bend fixing arrangement according to one embodiment of the present invention.

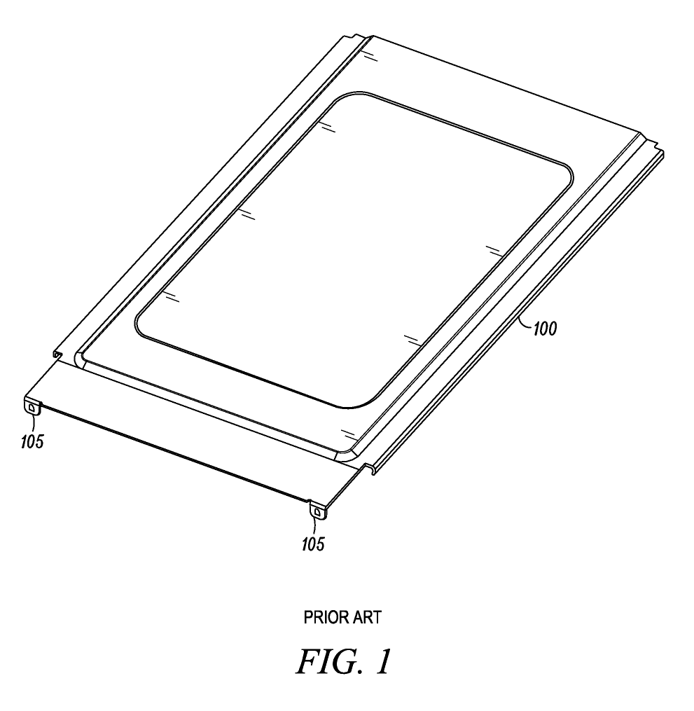

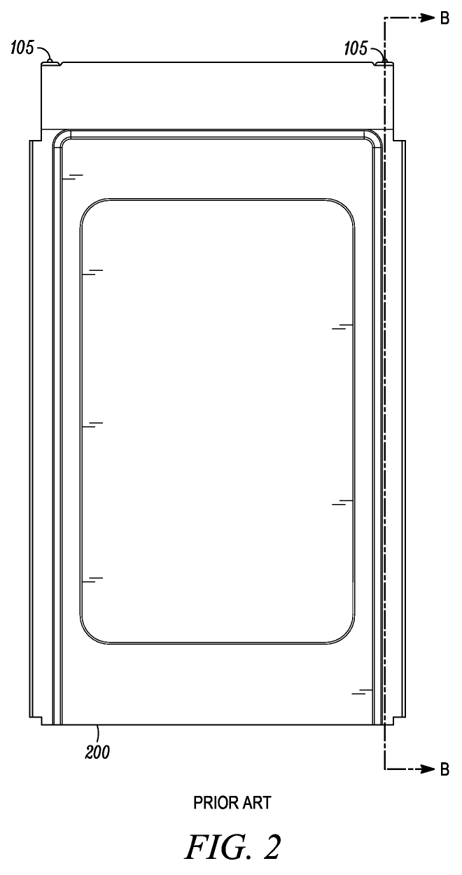

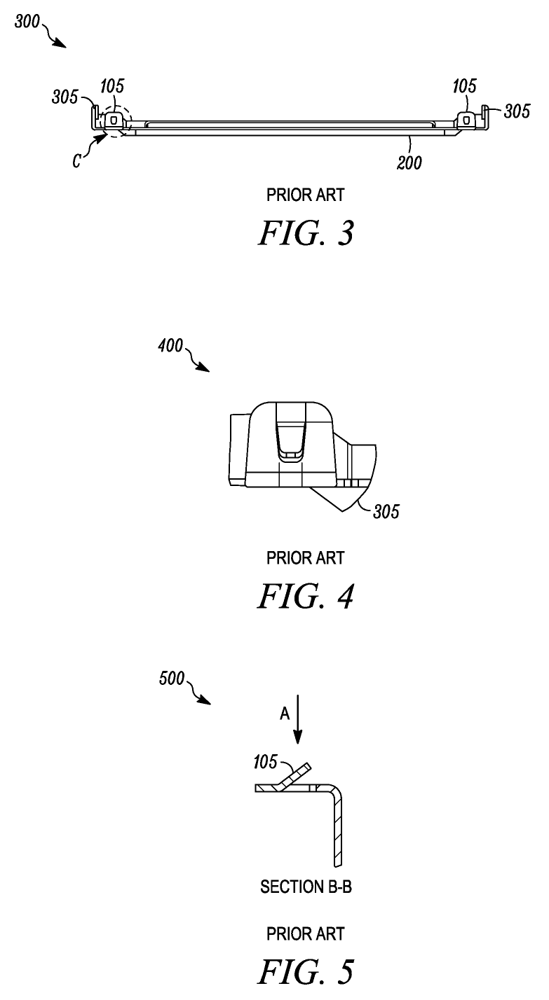

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION OF EMBODIMENTS OF THE INVENTION

Before describing in detail embodiments that are in accordance with the present invention, it should be observed that the embodiments reside primarily in combinations of method steps and apparatus components related to a card structure and method of assembly thereof. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

In one embodiment of the present invention, a card structure comprises a casing arranged to fit around an electrical connector. At least one foldable side tab is located on the casing such that when the at least one foldable side tab is folded it mechanically attaches the casing to the electrical connector. In this manner, by attaching the frame to the connector in the aforementioned manner, the frame, connector and a bottom (or associated top) cover are more securely attached. Furthermore, the tab fixing arrangement is more robust than a snap-fit fixing arrangement due to the increased mechanical strength. In addition, the aforementioned tab fixing arrangement does not suffer from the conductive burr problems associated with a snap-fit arrangement.

In one embodiment of the present invention, at least two foldable side tabs may be located on the casing to mechanically attach the casing to the electrical connector when folded.

In one embodiment of the present invention, the at least one foldable side tab may be located adjacent the electrical connector when the casing is mechanically attached to the electrical connector.

In one embodiment of the present invention, the casing may be a metal frame. In this manner, there is no requirement to use complex and expensive plastic frame molding technology to produce a card structure.

In one embodiment of the present invention, the casing may be arranged to fit around a Personal Computer Memory Card International Association (PCMCIA) electronic card.

In one embodiment of the present invention, a method of assembling a card structure is described. The method comprises folding at least one foldable side tab located on a casing of the card structure around an electrical connector, such that the at least one foldable side tab mechanically attaches the casing to the electrical connector.

One embodiment of the present invention will be described in terms of a PCMCIA card structure and method of manufacture thereof. However, it will be appreciated by a skilled artisan that the inventive concept herein described may be embodied in any type of PC card and method of manufacture thereof.

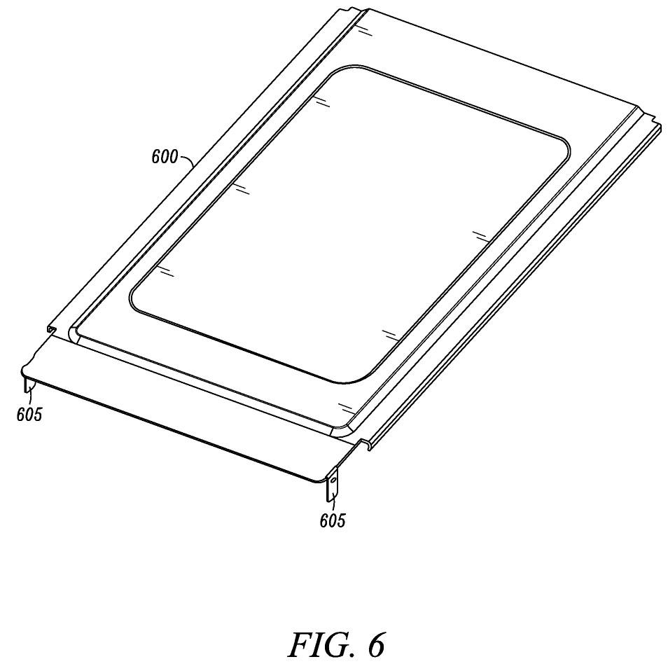

Referring now to FIG. 6, a plan view of a PCMCIA card casing structure 600 is illustrated in accordance with one embodiment of the present invention. The PCMCIA card casing structure 600 comprises foldable side-bend fixing arrangements (tabs) that, when the casing is affixed to the PCMCIA card, are folded over the bottom of a metal frame, thereby securely fixing and enclosing the PCMCIA card.

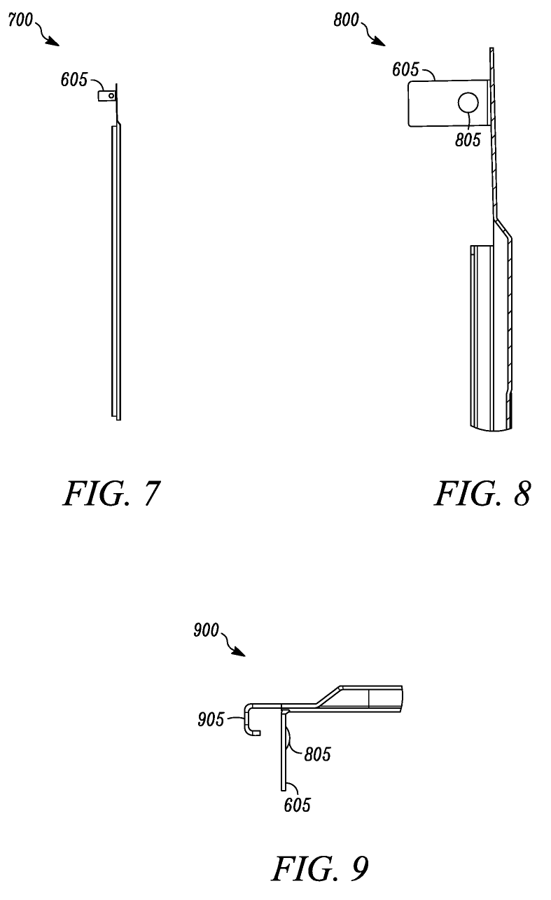

A sectional (side) view 700 along a longitudinal edge of PCMCIA card casing structure is illustrated in FIG. 7. In addition, a more detailed sectional (side) view 800 along a longitudinal edge of PCMCIA card casing structure is illustrated in FIG. 8. Here, the foldable side bend fixing arrangement is illustrated with a nodule 805, which may be a small dimple that is used to close the gap between the bottom cover sheet metal and casting frame. Thus, in this manner, the dimple makes the assembly of the PCMCIA card casing structure easier, as all mating parts are kept in place before folding the side tabs

Referring now to FIG. 9, a detailed end view 900 of a foldable side bend fixing arrangement is illustrated according to one embodiment of the present invention. Here, it is clearly shown that the foldable side bend has sufficient depth (i.e. below the lip 905 that attaches the frame to the PCMCIA card) to securely fix the frame to the PCMCIA card.

In one embodiment of the present invention, the two foldable side bends (tabs) are manufactured as resilient metal fixing arrangements that, when assembled, are able to mechanically attach the frame onto the PC card such that there is no gap between the bottom cover of the PC card structure and the frame, unlike the known prior art solution. In this manner, the metal casting frame is used like a chassis.

Thus, by introducing an additional step in the assembly process, the side bends 605 are resiliently folded over the frame into place. Advantageously, the foldable side bends 605 are placed distal from the 68-pin connector, thereby clamping the casing to the PC card structure and ensuring a tight fit of the casing to the PC card structure without limiting access to the 68-pin connector.

In one embodiment of the present invention, the foldable side bends are configured as part of a bottom cover sheet metal part. In an alternative embodiment of the present invention, it is envisaged that the foldable side bends may be configured as part of a top cover sheet metal part.

In one embodiment of the present invention, the assembly of the PCMCIA card is performed as follows. First, the 68-pin connector is soldered onto the PCMCIA printed circuit board. Thereafter, the printed circuit board and 68-pin connector are installed in the metal casting frame. At this stage, it is noteworthy that the connector is able to move upwards in a vertical direction, but is unable to move downwards in a vertical direction, as it is secured by the metal casting frame.

Finally, the bottom sheet metal cover, with the foldable side bend fixing arrangement, is then attached to the PCMCIA card structure, by bending the foldable side bend fixing arrangement over the metal casting frame using a simple mechanical tool. Thus, the sheet metal cover is attached to the metal casting frame and the 68-pin connector is now unable to move upwards in a vertical direction.

It will be understood that the improved PC card structure and method of manufacture thereof, as described above, aims to provide at least one or more of the following advantages:

(i) By attaching the cover to the 68 pin connector in the aforementioned manner, the frame, connector and bottom cover are more securely attached.

(ii) The method of manufacturing the PCMCIA card is improved using a less complex mechanism for securely attaching the respective covers to the frame.

(iii) The tab fixing arrangement is more robust than a snap-fit fixing arrangement due to the increased mechanical strength.

(iv) There is no gap between the metal cover and the frame.

(v) The aforementioned tab fixing arrangement does not suffer from the conductive burr problems associated with a snap-fit.

(vi) The aforementioned tab fixing arrangement provides robustness against bending deflection and twist movement of the PC card.

(vii) There is no requirement to use complex and expensive plastic frame molding technology as metal frames can be used.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Thus, an improved PC card structure and method of assembly thereof have been described, wherein the aforementioned disadvantages with prior art arrangements have been substantially alleviated.

We claim:

1. A card structure comprising a casing arranged to fit around an electrical connector, wherein at least one foldable side tab is located on the casing such that when the at least one foldable side tab is folded it mechanically attaches the casing to the electrical connector.

2. The card structure of claim 1 wherein at least two foldable side tabs are located on the casing to mechanically attach the casing to the electrical connector when folded.

3. The card structure of claim 1 wherein the at least one foldable side tab is located adjacent the electrical connector when the casing is mechanically attached to the electrical connector.

4. The card structure of claim 1 wherein the casing is a metal frame.

5. The card structure of claim 1 wherein the casing is arranged to fit around a Personal Computer Memory Card International Association (PCMCIA) electronic card.

6. A method of assembling a card structure, the method comprising:
folding at least one foldable side tab located on a casing of the card structure around an electrical connector, such that the at least one foldable side tab mechanically attaches the casing to the electrical connector.

7. The method of assembling a card structure of claim 5 further comprising folding at least one further foldable side tab located on the casing thereby mechanically attaching the casing to the electrical connector.

8. The method of assembling a card structure of claim 5 wherein the at least one foldable side tab is located adjacent the electrical connector when assembled around the electrical connector.
